(19) United States
(12) Patent Application Publication
(10) Pub. No.: US 2015/0188501 A1
(43) Pub. Date: Jul. 2, 2015

(54) POWER AMPLIFYING APPARATUS

(71) Applicant: SAMSUNG ELECTRO-MECHANICS CO., LTD., Suwon-Si (KR)

(72) Inventors: Jae Hyouck CHOI, Suwon-Si (KR); Jeong Hoon KIM, Suwon-Si (KR); Suk Chan KANG, Suwon-Si (KR); Joong Jin NAM, Suwon-Si (KR); Kyu Jin CHOI, Suwon-Si (KR); Kwang Du LEE, Suwon-Si (KR); Kyung Hee HONG, Suwon-Si (KR)

(73) Assignee: SAMSUNG ELECTRO-MECHANICS CO., LTD., Suwon-Si (KR)

(21) Appl. No.: 14/273,396

(22) Filed: May 8, 2014

(30) Foreign Application Priority Data
Dec. 30, 2013 (KR) 10-2013-0167690

(51) Int. Cl. H03F 1/56; H03F 3/193; H03F 3/68; H03F 3/195

(52) U.S. Cl. CPC H03F 1/56; H03F 3/195; H03F 3/193; H03F 3/68; H03F 2200/318

(57) ABSTRACT

A power amplifying apparatus may include a first amplifying unit receiving power and amplifying a high frequency signal, a second amplifying unit receiving the power and amplifying the high frequency signal from the first amplifying unit, and a control unit controlling an operation of the first amplifying unit or the second amplifying unit. The first amplifying unit and the control unit are disposed on a complementary metal oxide semiconductor (CMOS) substrate, and the second amplifying unit is disposed on a GaAs substrate.

### CROSS-REFERENCE TO RELATED APPLICATION

This application claims the benefit of Korean Patent Application No. 10-2013-0167690 filed on Dec. 30, 2013, with the Korean Intellectual Property Office, the disclosure of which is incorporated herein by reference.

### BACKGROUND

The present disclosure relates to a power amplifying apparatus.

In general, in addition to the existing 3G mobile communications scheme, a 4G mobile communications scheme, known as Long Term Evolution (LTE) has emerged with developments in wireless communications technology. That is, 4G mobile communications networks has been added to existing 2G and 3G mobile communications networks, and thus, the amount of frequency bands that must be supported by wireless communications terminals have gradually increased.

As described above, due to the emergence of new communications networks and increases in amount of frequency bands required to be supported by wireless communications terminals, the number of power amplifier modules (PAMs) required for use in a single mobile phone has also increased.

Accordingly, desired wireless terminal characteristics include features such as low power consumption, low price, compact size, high data transfer rates, a software defined radio (SDR, multiple standards support function) and the like.

Largely, two types of PAM structure are used according to the related art. A method of using a heterojunction bipolar transistor (HBT) formed of a GaAs-based material, a compound semiconductor material, as well as a method of using a Si-based bulk complementary metal oxide semiconductor (CMOS) or silicon-on-insulator (SOI) CMOS are mainly used.

A PAM that uses GaAs, as described above, has excellent electrical characteristics but requires high manufacturing costs.

Moreover, a PAM that uses a Si-based CMOS according to the related art is cost-effective but has a lower breakdown voltage than a PAM using a GaAs-based material, and thus, electrical characteristics thereof may be degraded. To increase the breakdown voltage of such a PAM, that is, to provide a high power output, the stacking of a plurality of amplifiers is inevitable, and thus, the surface area of the PAM may be increased.

Accordingly, to design a transmission structure having a high transmission rate, a power amplifier having a high degree of linearity is required, but a CMOS power amplifier has a lower degree of linearity than a GaAs power amplifier, and thus a transmission structure for compensation of such a lack of linearity is urgently required.

### SUMMARY

An exemplary embodiment in the present disclosure may provide a power amplifying apparatus including a first amplifying unit disposed on a complementary metal oxide semiconductor (CMOS) substrate, a control unit, and a second amplifying unit disposed on a GaAs substrate, thereby reducing material costs simultaneously with securing excellent electrical characteristics.

According to an exemplary embodiment in the present disclosure, a power amplifying apparatus may include a first amplifying unit receiving power and amplifying a high frequency signal, a second amplifying unit receiving the power and amplifying the high frequency signal from the first amplifying unit, and a control unit controlling an operation of the first amplifying unit or the second amplifying unit. The first amplifying unit and the control unit may be disposed on a complementary metal oxide semiconductor (CMOS) substrate, and the second amplifying unit may be disposed on a GaAs substrate.

The power amplifying apparatus may further include a first matching circuit unit matching impedance of a signal transfer path between an signal input terminal through which a high frequency signal is provided to the first amplifying unit, and the first amplifying unit.

The first matching circuit unit may be disposed on the CMOS substrate.

The power amplifying apparatus may further include a second matching circuit unit matching impedance of a signal transfer path between the first amplifying unit and the second amplifying unit.

The second matching circuit unit may be disposed on the CMOS substrate.

The power amplifying apparatus may further include an output matching circuit unit matching impedance of a signal transfer path between a signal output terminal through which an output signal amplified by the second amplified unit is output and the second amplifying unit.

According to an exemplary embodiment in the present disclosure, a power amplifying apparatus may include a first amplifying unit receiving power and amplifying a high frequency signal, a second amplifying unit receiving the power and amplifying the high frequency signal from the first amplifying unit, a third amplifying unit receiving the power and amplifying the high frequency signal from the second amplifying unit, and a control unit controlling an operation of the first amplifying unit, the second amplifying unit or the third amplifying unit. The first amplifying unit, the second amplifying unit, and the control unit may be disposed on a complementary metal oxide semiconductor (CMOS) substrate, and the third amplifying unit may be disposed on a GaAs substrate.

The power amplifying apparatus may further include a first matching circuit unit matching impedance of a signal transfer path between a signal input terminal through which a high frequency signal is provided to the first amplifying unit, and the first amplifying unit.

The first matching circuit unit may be disposed on the CMOS substrate.

The power amplifying apparatus may further include a second matching circuit unit matching impedance of a signal transfer path between the first amplifying unit and the second amplifying unit.

The second matching circuit unit may be disposed on the CMOS substrate.

The power amplifying apparatus may further include a third matching circuit unit matching impedance of a signal transfer path between the second amplifying unit and the third amplifying unit.

The third matching circuit unit may be disposed on the CMOS substrate.

The power amplifying apparatus may further include an output matching circuit unit matching impedance of a signal transfer path between a signal output terminal through which an output signal amplified by the third amplified unit is output, and the third amplifying unit.

According to an exemplary embodiment in the present disclosure, a power amplifying apparatus may include a plurality of amplifying units receiving power and sequentially amplifying high frequency signals, and a control unit controlling operations of the plurality of amplifying units. Among the plurality of amplifying units, an amplifying unit connected to a final output terminal may be disposed on a GaAs substrate, and the remainder of the amplifying units with the exception of the amplifying unit connected to the final output terminal, and the control unit, may be disposed on a complementary metal oxide semiconductor (CMOS) substrate.

The power amplifying apparatus may further include an input matching circuit unit matching impedance of a signal transfer path between a signal input terminal through which a high frequency signal is provided to the plurality of amplifying units, and the plurality of amplifying units, and a plurality of internal matching circuit units matching impedance of signal transfer paths between the plurality of amplifying units. The input matching circuit unit and the plurality of internal matching circuit units may be disposed on the CMOS substrate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a power amplifying apparatus according to an exemplary embodiment of the present disclosure;

FIG. 2 is a block diagram illustrating a power amplifying apparatus according to another exemplary embodiment of the present disclosure;

FIG. 3 is a block diagram illustrating a power amplifying apparatus according to another exemplary embodiment of the present disclosure;

FIG. 4 is a block diagram illustrating a power amplifying apparatus according to another exemplary embodiment of the present disclosure; and

FIG. 5 is a graph showing a peak voltage of power output from an amplifying unit.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

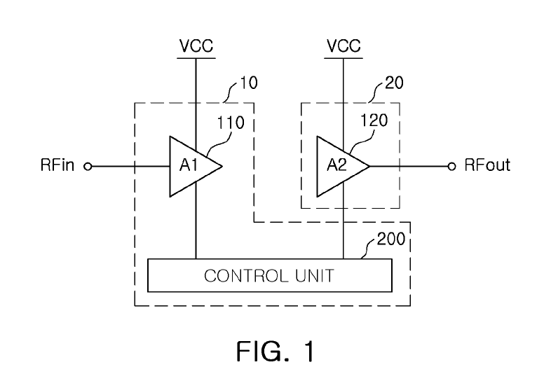

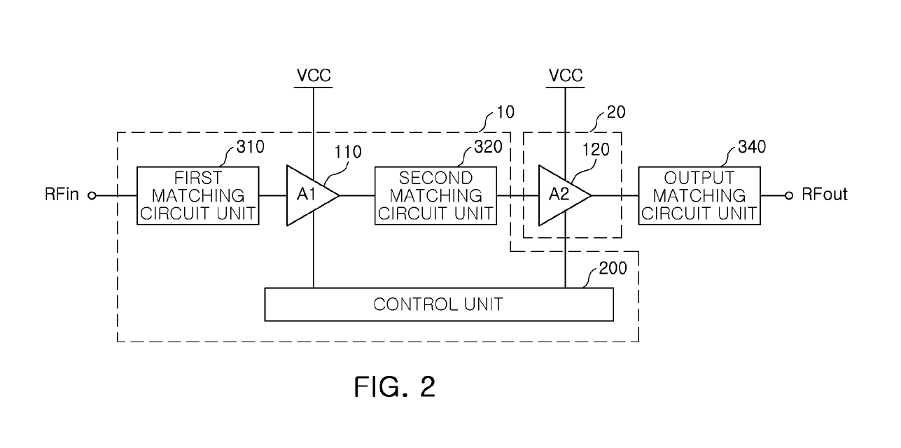

FIG. 1 is a block diagram illustrating a power amplifying apparatus according to an exemplary embodiment of the present disclosure. FIG. 2 is a block diagram illustrating a power amplifying apparatus according to another exemplary embodiment of the present disclosure.

Referring to FIGS. 1 and 2, the power amplifying apparatus according to the exemplary embodiment of the present disclosure may include a first amplifying unit 110 amplifying a high frequency signal, a second amplifying unit 120 amplifying the high frequency signal from the first amplifying unit 110, and a control unit 200 controlling operations of the first amplifying unit 110 and the second amplifying unit 120.

According to an exemplary embodiment of the present disclosure, the power amplifying apparatus may further include a first matching circuit unit 310 matching impedance of a signal transfer path between the first amplifying unit 110 and a signal input terminal through which a high frequency signal is input.

According to an exemplary embodiment of the present disclosure, the power amplifying apparatus may further include a second matching circuit unit 320 matching impedance of a signal transfer path between the first amplifying unit 110 and the second amplifying unit 120.

Also, according to an exemplary embodiment of the present disclosure, the power amplifying apparatus may further include an output matching circuit unit 340 matching impedance of a signal transfer path between a signal output terminal RFout through which an output signal amplified by the second amplifying unit 120 is output and the second amplifying unit 120.

The first amplifying unit 110 may receive power and amplify a high frequency signal. The first amplifying unit 110 may be disposed on a CMOS substrate 10 together with the control unit 200. The first amplifying unit 110 disposed on the CMOS substrate 10 is a low power amplifier, and may amplify an input high frequency signal according to a preset gain. A gain of the first amplifying unit 110 may be set in consideration of a breakdown voltage of the first amplifying unit 110.

The second amplifying unit 120 may receive power and amplify the high frequency signal from the first amplifying unit 110. For example, the second amplifying unit 120 is a high power amplifier of the power amplifying apparatus, and may amplify, once more, the high frequency signal, which has been amplified by the first amplifying unit 110, according to a preset gain. The second amplifying unit 120 may be disposed on a GaAs substrate 20. According to an exemplary embodiment of the present disclosure, the second amplifying unit 120 may be one of a heterojunction bipolar transistor (HBT) and a high electron mobility transistor (HEMT) disposed on the GaAs substrate 20.

The control unit 200 may be disposed on the CMOS substrate 10 together with the first amplifying unit 110, and may control operations of the first amplifying unit 110 and the second amplifying unit 120.

The first matching circuit unit 310 may match impedance of a signal transfer path between the first amplifying unit 110 and a signal input terminal through which a high frequency signal is input. The first matching circuit unit 310 may be disposed on the CMOS substrate 10 together with the first amplifying unit 110 and the control unit 200.

The second matching circuit unit 320 may match impedance of a signal transfer path between the first amplifying unit 110 and the second amplifying unit 120, and like the first matching circuit unit 310, the second matching circuit unit 320 may also be disposed on the CMOS substrate 10 together with the first amplifying unit 110 and the control unit 200.

The output matching circuit unit 340 may match impedance of a signal transfer path between a signal output terminal through which an output signal amplified by the second amplifying unit 120 is output and the second amplifying unit 120. Here, the output matching circuit unit 340 may be mounted on a surface of a printed circuit board on which the CMOS substrate 10 and the GaAs substrate 20 are mounted.

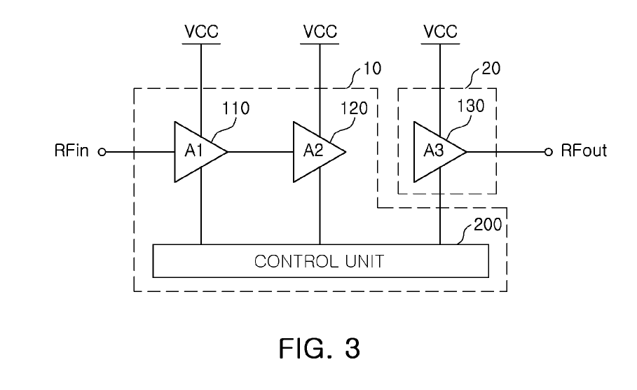

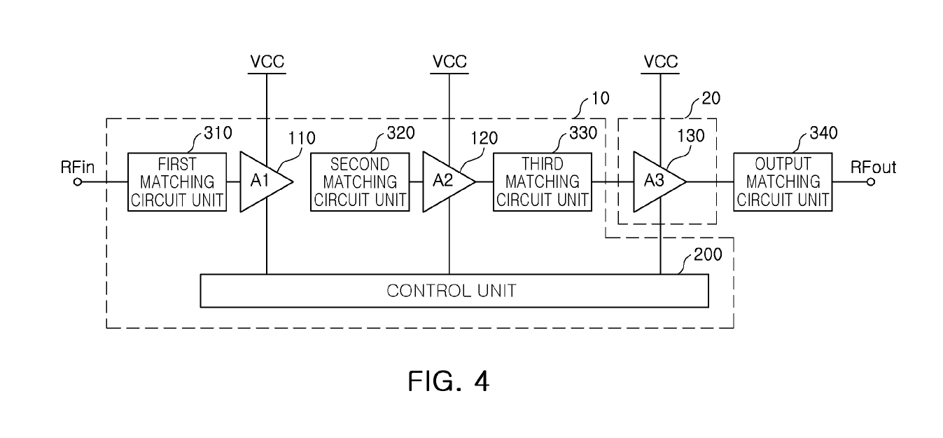

FIG. 3 is a block diagram illustrating a power amplifying apparatus according to another exemplary embodiment of the present disclosure. FIG. 4 is a block diagram illustrating a power amplifying apparatus according to another exemplary embodiment of the present disclosure.

Referring to FIGS. 3 and 4, the power amplifying apparatus according to another exemplary embodiment of the present disclosure may include a first amplifying unit 110 amplifying a high frequency signal, a second amplifying unit 120 amplifying the high frequency signal from the first amplifying unit 110, a third amplifying unit 130 amplifying the high frequency signal from the second amplifying unit 120, and a control unit 200 controlling operations of the first amplifying unit 110, the second amplifying unit 120, and the third amplifying unit 130.

According to an exemplary embodiment of the present disclosure, the power amplifying apparatus may further include a first matching circuit unit 310 matching impedance of a signal transfer path between the first amplifying unit 110 and an signal input terminal through which a high frequency signal is provided to the first amplifying unit 110.

According to another embodiment of the present disclosure, the power amplifying apparatus may further include a second matching circuit unit 320 matching impedance of a signal transfer path between the first amplifying unit 110 and the second amplifying unit 120.

According to another embodiment of the present disclosure, the power amplifying apparatus may further include a third matching circuit unit 330 matching impedance of a signal transfer path between the second amplifying unit 120 and the third amplifying unit 130.

According to another embodiment of the present disclosure, the power amplifying apparatus may further include an output matching circuit unit 340 matching impedance of a signal transfer path between a signal output terminal through which an output signal amplified by the third amplifying unit 130 is output and the third amplifying unit 130.

The first amplifying unit 110 may receive power and amplify a high frequency signal, and the second amplifying unit 120 may receive the power and amplify the high frequency signal from the first amplifying unit 110.

Here, the first amplifying unit 110 and the second amplifying unit 120 may be disposed on a CMOS substrate 10 together with the control unit 200. As breakdown voltages of the first amplifying unit 110 and the second amplifying unit 120 disposed on the CMOS substrate 10 are relatively low, the first and second amplifying units may constitute a low power amplifier together, and may amplify an input high frequency signal according to a preset gain.

Here, gains of the first amplifying unit 110 and the second amplifying unit 120 may be respectively set in consideration of the breakdown voltages of the first amplifying unit 110 and the second amplifying unit 120.

The third amplifying unit 130 may receive power and amplify the high frequency signal from the second amplifying unit 120. For example, the third amplifying unit 130, a high power amplifier of the power amplifying apparatus, may amplify the high frequency signal amplified by the second amplifying unit 120 one more time according to a preset gain.

Here, the third amplifying unit 130 may be disposed on a GaAs substrate 20. According to an exemplary embodiment of the present disclosure, the third amplifying unit 130 may be one of a HBT and a HEMT disposed on the GaAs substrate 20.

The control unit 200 may be disposed on the CMOS substrate 10 together with the first amplifying unit 110 and the second amplifying unit 120, and may control operations of the first amplifying unit 110, the second amplifying unit 120, and the third amplifying unit 130.

The first matching circuit unit 310 may match impedance of a signal transfer path between the first amplifying unit 110 and a signal input terminal through which a high frequency signal is input, and the first matching circuit unit 310 may be disposed on the CMOS substrate 10 together with the first amplifying unit 110, the second amplifying unit 120, and the control unit 200.

The second matching circuit unit 320 may match impedance of a signal transfer path between the first amplifying unit 110 and the second amplifying unit 120, and the second matching circuit unit 320 may be disposed on the CMOS substrate 10 together with the first amplifying unit 110, the second amplifying unit 120, and the control unit 200.

The third matching circuit unit 330 may match impedance of a signal transfer path between the second amplifying unit 120 and the third amplifying unit 130, and like the first amplifying unit 110 or the second amplifying unit 120, the third matching circuit unit 330 may also be disposed on the CMOS substrate 10 together with the first amplifying unit 110, the second amplifying unit 120, and the control unit 200.

The output matching circuit unit 340 may match impedance of a signal transfer path between the third amplifying unit 130 and a signal output terminal through which an output signal amplified by the third amplifying unit 130 is output. Here, the output matching circuit unit 340 may be mounted on a surface of a printed circuit board on which the CMOS substrate 10 and the GaAs substrate 20 are mounted.

According to another exemplary embodiment of the present disclosure, the power amplifying apparatus may include a plurality of amplifying units 110, 120, and 130 that sequentially receive power and amplify a high frequency signal, and a control unit 200 controlling operations of the plurality of amplifying units 110, 120, and 130, and the amplifying unit 130 that is connected to a final output terminal and that is disposed on the GaAs substrate 20, and remaining amplifying units 110 and 120, except for the amplifying unit 130 that is connected to the final output terminal, and the control unit 200 may be disposed on the CMOS substrate 10.

Here, the power amplifying apparatus may further include an input matching circuit unit, for example, 310 of FIG. 4, matching impedance between the amplifying unit 110 located at a first terminal, among the plurality of amplifying units 110, 120 and 130, and a signal input terminal, a plurality of internal matching circuit units, for example, 320 and 330 of FIG. 4, matching impedance among the plurality of amplifying unit 110, 120, and 130, and an output matching circuit unit, for example, 340 of FIG. 4, matching impedance between the amplifying unit 130 at a final terminal and a signal output terminal.

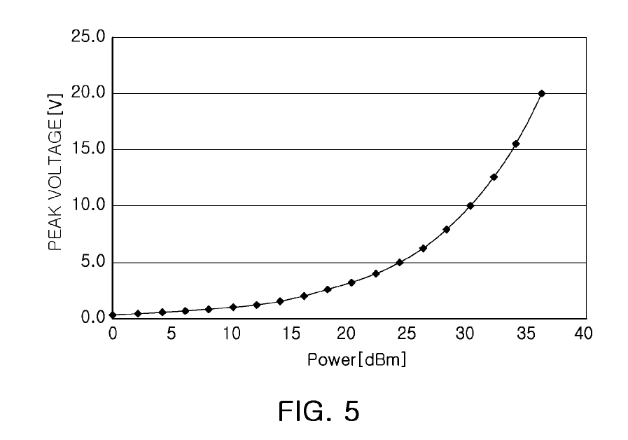

FIG. 5 is a graph showing a peak voltage of power output from an amplifying unit.

Referring to FIG. 5, the higher power output from the amplifying units 110, 120, and 130 is, the higher peak voltages applied to the amplifying units 110, 120, and 130 are. Here, the peak voltage may be calculated based on Equation 1.

Vpk=\sqrt{2*ZL*power} [Equation 1]

where Vpk denotes a peak voltage, ZL denotes impedance, and power denotes output power.

According to the power amplifying apparatus of FIG. 1 of the exemplary embodiment of the present disclosure, the first amplifying unit 110 disposed on the CMOS substrate 10 has a lower breakdown voltage than the second amplifying unit 120 disposed on the GaAs substrate 20, and thus, a peak voltage according to power output by using the first amplifying unit 110 may be set to be lower than the breakdown voltage of the first amplifying unit 110.

For example, when power to be finally amplified and output by the power amplifying apparatus is 30 dBm, a magnitude of power that is amplified and output by using the first amplifying unit 110 may be set in consideration of the breakdown voltage of the first amplifying unit 110.

Here, when the breakdown voltage of the first amplifying unit 110 disposed on the CMOS substrate 10 is 2 V, a peak voltage of the first amplifying unit 110 is to be lower than 2 V.

Consequently, a gain, at which an output of 15 dBm allowing a peak voltage to be lower than 2 V is provided, may be set for the first amplifying unit 110, and the second amplifying unit 120 may amplify the amplified output of 15 dBm from the first amplifying unit 110, to 30 dBm.

According to exemplary embodiments of the present disclosure, the power amplifying apparatus includes the first amplifying unit disposed on the CMOS substrate, the control unit, and the second amplifying unit disposed on the GaAs substrate, whereby the material costs may be reduced simultaneously with securing excellent electrical characteristics.

While exemplary embodiments have been shown and described above, it will be apparent to those skilled in the art that modifications and variations could be made without departing from the spirit and scope of the present disclosure as defined by the appended claims.

What is claimed is:

1. A power amplifying apparatus comprising:
a first amplifying unit configured to receive power and amplifying a high frequency signal;
a second amplifying unit configured to receive the power and amplifying the high frequency signal from the first amplifying unit; and
a control unit configured to control an operation of the first amplifying unit or the second amplifying unit,
wherein the first amplifying unit and the control unit are disposed on a complementary metal oxide semiconductor (CMOS) substrate, and the second amplifying unit is disposed on a GaAs substrate.

2. The power amplifying apparatus of claim 1, further comprising a first matching circuit unit matching impedance of a signal transfer path between a signal input terminal through which a high frequency signal is provided to the first amplifying unit, and the first amplifying unit.

3. The power amplifying apparatus of claim 2, wherein the first matching circuit unit is disposed on the CMOS substrate.

4. The power amplifying apparatus of claim 1, further comprising a second matching circuit unit matching impedance of a signal transfer path between the first amplifying unit and the second amplifying unit.

5. The power amplifying apparatus of claim 4, wherein the second matching circuit unit is disposed on the CMOS substrate.

6. The power amplifying apparatus of claim 1, further comprising an output matching circuit unit matching impedance of a signal transfer path between a signal output terminal through which an output signal amplified by the second amplified unit is output and the second amplifying unit.

7. A power amplifying apparatus comprising:
a first amplifying unit configured to receive power and amplify a high frequency signal;
a second amplifying unit configured to receive the power and amplify the high frequency signal from the first amplifying unit;
a third amplifying unit configured to receive the power and amplify the high frequency signal from the second amplifying unit; and
a control unit configured to control an operation of the first amplifying unit, the second amplifying unit or the third amplifying unit,
wherein the first amplifying unit, the second amplifying unit, and the control unit are disposed on a complementary metal oxide semiconductor (CMOS) substrate, and the third amplifying unit is disposed on a GaAs substrate.

8. The power amplifying apparatus of claim 7, further comprising a first matching circuit unit matching impedance of a signal transfer path between a signal input terminal through which a high frequency signal is provided to the first amplifying unit, and the first amplifying unit.

9. The power amplifying apparatus of claim 8, wherein the first matching circuit unit is disposed on the CMOS substrate.

10. The power amplifying apparatus of claim 7, further comprising a second matching circuit unit matching impedance of a signal transfer path between the first amplifying unit and the second amplifying unit.

11. The power amplifying apparatus of claim 10, wherein the second matching circuit unit is disposed on the CMOS substrate.

12. The power amplifying apparatus of claim 7, further comprising a third matching circuit unit matching impedance of a signal transfer path between the second amplifying unit and the third amplifying unit.

13. The power amplifying apparatus of claim 12, wherein the third matching circuit unit is disposed on the CMOS substrate.

14. The power amplifying apparatus of claim 7, further comprising an output matching circuit unit matching impedance of a signal transfer path between a signal output terminal through which an output signal amplified by the third amplified unit is output, and the third amplifying unit.

15. A power amplifying apparatus comprising:
a plurality of amplifying units configured to receive power and sequentially amplify high frequency signals; and
a control unit configured to control operations of the plurality of amplifying units,
wherein among the plurality of amplifying units, an amplifying unit connected to a final output terminal is disposed on a GaAs substrate, and the remainder of the amplifying units with the exception of the amplifying unit connected to the final output terminal, and the control unit, are disposed on a complementary metal oxide semiconductor (CMOS) substrate.

16. The power amplifying apparatus of claim 15, further comprising:
an input matching circuit unit configured to match impedance of a signal transfer path between a signal input terminal through which a high frequency signal is provided to the plurality of amplifying units, and the plurality of amplifying units; and
a plurality of internal matching circuit units that match impedance of signal transfer paths between the plurality of amplifying units,
wherein the input matching circuit unit and the plurality of internal matching circuit units are disposed on the CMOS substrate.
